(19) United States
(12) Patent Application Publication
(10) Pub. No.: US 2015/0207538 A1
(43) Pub. Date: Jul. 23, 2015

(54) AUTOMATIC CONFIGURATION OF A DEVICE FOR COMMUNICATION

(71) Applicant: SIEMENS AKTIENGESELLSCHAFT, München (DE)

(72) Inventor: Karstein Kristiansen, Trondheim (NO)

(21) Appl. No.: 14/419,159

(22) PCT Filed: Jun. 20, 2013
(86) PCT No.: PCT/EP2013/062839

§ 371 Date: Feb. 2, 2015

(30) Foreign Application Priority Data
Aug. 1, 2012 (EP) 12178886.3

(51) Int. Cl. H04B 1/58; G01R 19/00; H04B 3/46

(52) U.S. Cl. CPC H04B 1/586; H04B 3/46; G01R 19/00

(57) ABSTRACT

A method for configuring a device to receive an electrical input signal includes: generating the electrical input signal in compliance with a predetermined communication technology; performing a measurement of the electrical input signal; selecting, based on a result of the measurement, the predetermined communication technology for receiving the electrical input signal at the device from a plurality of available communication technologies supported by the device; and actuating the device to receive the electrical input signal according to the predetermined communication technology.

### RELATED APPLICATIONS

This application is the National Stage of International Application No. PCT/EP2013/062839, filed Jun. 20, 2013, which claims the benefit of European Patent Application No. EP 12178886.3, filed Aug. 1, 2012. The entire contents of both documents are hereby incorporated herein by reference.

### TECHNICAL FIELD

The present teachings relate generally to a method and an apparatus for configuring a device for reception of an electrical input signal (e.g., a communication signal).

### BACKGROUND

A subsea installation (e.g., an oil/gas exploration system) may be based on old and slow communication standards and technologies. A number of subsea units may be connected to a communication network to exchange data for controlling the subsea units (e.g., pumps or measuring devices).

U.S. Pat. No. 6,654,351 describes a configurable multi-protocol vehicle communication circuit and method. Communication terminals and are placed in a high impedance state. The microprocessor senses a first voltage and a second voltage at the communication terminal while in the high-impedance state.

European Patent Document No. EP 0 639 916 A2 describes a system and method for connection of multiple protocol terminals. A network port device automatically configures a system having network workstations and corresponding network equipment of various physical protocols.

U.S. Pat. No. US 7,058,075 B1 describes a self-configuring interface for communication protocols. An interface module has a network interface. A voltage is detected at an unused contact to identify a networking protocol for configuring the apparatus.

A communication network that includes a number of old subsea units may be difficult to upgrade.

### SUMMARY AND DESCRIPTION

The scope of the present invention is defined solely by the appended claims, and is not affected to any degree by the statements within this summary.

A method and apparatus for configuring a device (e.g., a subsea communication device) for reception of an electrical input signal may simplify the upgrading of existing communication networks (e.g., at a sea ground).

The present embodiments may obviate one or more of the drawbacks or limitations in the related art. For example, in some embodiments, a method for configuring a device for reception of an electrical input signal is provided. The method includes generating the input signal in compliance with a predetermined communication technology; performing a measurement of the input signal; selecting, based on a result of the measurement, a predetermined technology for receiving the input signal at the device from a plurality of available communication technologies supported by the device; and activating (e.g., enabling) the device to receive the input signal according to the predetermined communication technology. The generating of the input signal includes supplying a voltage signal to a cable having wires that are galvanically separated from each other. The performing of the measurement of the input signal includes testing which pair of wires of the cable carries the input signal. The pair is formed by a first wire and a second wire.

By way of example, the cable may have at least 4 wires. In some embodiments, the cable may have between 4 and 5 wires that are galvanically separated from each other.

In some embodiments, the device may be or may include a subsea unit (e.g., a pump, a compressor, a measuring device, or the like) operable at a sea ground. The device may be located 1000 m-4000 m below sea level (e.g., at a sea ground).

The method may be performed during a gas/oil exploration application. In some embodiments, the method may be performed when the device replaces an old device that is a member of a communication network. In some embodiments, the device may be configured for receiving an input signal while being a member of a communication network. One or more old devices may be replaced one by one with new devices. The new devices may be configured for the reception of the input signal in accordance with the present teachings. In some embodiments, the method may be performed during start up of the device.

Existing old devices or subsea units may be replaced one after another over several years until a complete upgrade of all units is achieved. The new devices may provide more advanced or novel communication technologies. These advanced or novel communication technologies may provide higher data transfer rates, higher security, and/or greater reliability. The device that is being configured by a method in accordance with the present teachings may be configured for communicating in both the old and also the new communication technology. Depending on the characteristics of the input signal to be supplied to the device, the communication interface of the device may be configured to appropriately receive the input signal. In some embodiments, the device (e.g., the new subsea unit that replaces the old subsea unit) may contain all of the various physical interfaces and may be configured to handle all of the various communication protocols, including the old communication protocols and the new communication protocols.

In some embodiments, during powering on of the device, a sense and select circuit (SASC) may receive the input signal (e.g., communication packages) and may decide the type of communication the input signal complies with based on the measurement (e.g., a voltage measurement) on the physical layer. The SASC unit or circuit may activate an appropriate receiver or interface for the detected input signal and may connect the correct receiver to the input signal. Whenever the device is activated so as to receive the input signal according to the predetermined communication technology, the device may keep the selected communication technology until a next power-on sequence. In some embodiments, the activation of the device to receive the input signal according to the predetermined communication technology may be performed only during a start-up or boot-up sequence of the device.

The input signal may be a regular signal generated by another device during normal operation of the communication network. Alternatively, the input signal may be an intentionally generated input signal that may have characteristics that simplify the measurement, or evaluation of the measurement, to select the predetermined communication technology from the plurality of available communication technologies.

Thus, a new communication infrastructure of the communication network may be upgraded step-by-step, while the existing communication infrastructure may still be used by the devices that are able to support only the existing communication technology. In some embodiments, old and new communication signaling is supported. The device that is being configured may decide the available communication signaling to use from the plurality of available communication technologies supported by the device.

In some embodiments, generating the input signal may include supplying a voltage signal to a cable having between 4 and 5 wires that are galvanically separated from each other.

The input signal may be carried by the cable (e.g., in some embodiments, by two wires of the cable). Using a cable may simplify the supply of the input signal. Further, the measurement may be carried out by contacting one or more wires of the cable and detecting a voltage at the one or more wires of the cable.

The performing of the measurement of the input signal includes determining (e.g., testing) which pair of wires of the cable carries the input signal. The pair is formed by a first wire and a second wire.

Testing which pair of wires of the cable carries the input signal may include measuring voltages between a number of pairs that may be formed from the wires of the cable. In some embodiments, all permutations of pairs of wires may be checked for voltages between the two wires of the pair. The performing of the measurement may thus be simplified.

In some embodiments, the measurement of the input signal includes comparing an electrical potential of the first wire and/or the second wire to a ground potential. If the potential of either of the first wire or the second wire is the ground potential, the RS 232 communication technology is selected.

The RS 232 communication technology may use a non-differential signal for representing a logical true and a logical false. In some embodiments, logical false may be represented by having an electrical potential of −3 V at the first wire and an electrical potential of the earth potential at the second wire. In some embodiments, a logical true value may be represented by having an electrical potential at the first wire of 10 V and an electrical potential at the second wire of the earth potential. The method may further determine other types of communication technologies that use a non-differential signal by performing further tests on the electrical input signal.

Thus, a simple manner of determining whether the input signal complies with the RS 232 communication technology is provided.

In some embodiments, the measurement of the input signal includes measuring a voltage (e.g., for plural communication clock cycles) between the first wire and the second wire.

A communication input signal may largely be represented by voltage signals. However, different communication technologies may utilize different voltage levels for representing logical false or logical true. In some embodiments, the logical values may be represented by voltages that are as an absolute value below 20 V (e.g., below 15 V). In some embodiments, the communication technology may utilize a differential input signal for representing logical false and logical true. Thus, a difference in electrical potentials between the first wire and the second wire may establish or define the logical value that is transferred by the input signal. In some embodiments, the logical value may be transferred during clock cycles, such that the logical value may be changed for each clock cycle. As a result, the method may facilitate handling of differential input signals and may differentiate between different differential input signals.

In some embodiments, if the maximum absolute value of the voltage is below 3 V, the Ethernet communication technology is selected.

The voltage between the first wire and the second wire may alternate between -2.5 V and +2.5 V when the Ethernet communication technology is used. For example, the voltage of −2.5 V may represent a logical false value and a voltage of +2.5 V may represent a logical true value. However, the absolute value of the voltage may be 2.5 V (e.g., may be below 3 V). Thus, a simple procedure to determine if the Ethernet communication technology is used is provided.

In some embodiments, if the maximum absolute value of the voltage is above 3 V but below 6 V, the RS 422 communication technology is selected.

The RS 422 communication technology may utilize a differential signal for communication. For example, a voltage of −6 V may represent a logical false value, and a voltage between the first wire and the second wire of +6 V may represent a logical true value. Thus, the input signal may have a maximum absolute value of the voltage that is below 6 V (and not below 3 V) when the RS 422 communication technology is utilized.

Thus, a simple procedure is provided for establishing that the input signal complies with the RS 422 communication technology.

It may be determined whether the input signal is carried by 2 wires or 4 wires. For example, the determination may be based on the format of the received input. The format may suggest 4-wire or 2-wire communication.

In some embodiments, if the maximum absolute value of the voltage is above 6 V, the RS 485 communication technology is selected.

For example, a voltage of −7 V between the first wire and the second wire may represent a logical false value, and a voltage of +12 V between the first wire and the second wire may represent a logical true value, when the input signal complies with the RS 485 communication technology.

Since RS 485 communication technology involves a voltage that is not larger than 12 V in absolute terms, a check may be made that the maximum absolute value of the voltage is below 12 V so that the input signal complies with RS 485 communication technology.

In some embodiments, the available communication technologies and the predetermined communication technology include data package-based protocols (e.g., in some embodiments, Ethernet, RS 485, RS 422, and/or RS 232).

The method may support selection of different kinds of communication protocols that use differential signals or non-differential signals. Whenever a new communication technology evolves that has certain voltage representations of logical false or logical true values, a skilled artisan may provide another test or check to detect the novel communication technology by performing one or more voltage measurements on the input signal.

Thus, a method for configuring a device in accordance with the present teachings is highly flexible and, in some embodiments, may support novel communication technologies to be developed in the future.

In some embodiments, the generating of the input signal includes generating a signal pattern that includes a time sequence of logical true and logical false values. The measurement is performed based on the signal pattern. In some embodiments, a clock speed of the predetermined communication technology is considered when the measurement is performed or when a result is derived from the performed measurement. In some embodiments, the measurement is performed across at least 10 clock cycles and, in some embodiments, between 100 and 1000 clock cycles.

The signal pattern may be known in advance and may be utilized to evaluate the performed measurement. In some embodiments, the signal pattern may include a sequence of logical true and false values. If the signals of logical false and true values are known in advance, the communication technology that the input signal complies with may be determined based on voltage measurements of the input signal.

The clock speed (e.g., the minimum time span during which a logical value may change) may be known when the measurement is performed. Thus, evaluation of the measurement may be further simplified. In addition, a measurement across a number of clock cycles may be taken into account to further improve accuracy of the method.

In some embodiments, the method for configuring the device further includes activating a transceiver or interface of the device that is appropriate for the communication technology, and actuating a switch to supply the input signal to the transceiver or interface.

Activating the transceiver or device may include turning on the transceiver or device and/or configuring the transceiver or device or interface. The transceiver or the interface of the device may, for example, be provided by an interface card or circuit. The interface card or circuit may be supported by the device but activation may involve switching on the interface card or circuit. By actuating the switch, the cable carrying the input signal may be connected to one or more input terminals of the transceiver or interface, thereby supplying the input signal to the transceiver or interface. Alternatively, the cable carrying the input signal may continuously be connected to all available transceivers or interfaces of the device, such that actuating the switch to supply the input signal to the transceiver or interface may be avoided.

The device may be configured to receive and interpret the electrical input signal. The device may supply the input signal in a number of different communication protocols or technologies, and may select the technology with which the input signal complies.

Thus, upgrading a communication network or one or more communication devices included in the network is facilitated and, in some embodiments, a stepwise upgrade of communication technologies may be implemented.

In some embodiments, the actuating of the switch includes connecting the first wire and the second wire to input terminals of the activated transceiver. The input signal carried by the first wire and the second wire is supplied to the transceiver.

In some embodiments, the actuating of the switch includes connecting a third wire of the cable and a fourth wire of the cable to output terminals of the activated transceiver (e.g., if the RS 422 technology or the RS 485 technology uses four wires). An output signal received or output by the transceiver may be supplied to the third wire and the fourth wire. The third wire and the fourth wire may function as output wires of the communication cable.

In some embodiments, the method further includes notifying the device about the communication technology to be used.

The device may utilize the communication technology that has been detected as the communication technology with which the input signal complies (e.g., the predetermined communication technology) for subsequent communications or output. Alternatively, the device may utilize a most recent or most advanced communication technology to communicate output signals of the device to other members of the communication network. In some embodiments, the predetermined communication technology with which the input signal complies may be different from a communication technology utilized by the device for outputting output signals to other members of the communication network. As a result, communication speed may be increased to improve the communication network.

It is to be understood that the features described in connection with a method for configuring a device for reception of an electrical input signal in accordance with the present teachings may likewise be applied—individually or in any combination—to an apparatus in accordance with the present teachings, and vice versa.

In some embodiments, an apparatus for configuring a device for reception of an electrical input signal is provided. The apparatus includes a measuring section configured to perform a measurement of an input signal complying with a predetermined communication technology; a selection section configured to select, based on a result of the measurement, a predetermined technology for receiving the input signal at the device from a plurality of available communication technologies supported by the device; and a control section configured to activate the device to receive the input signal according to the predetermined communication technology. The input signal is generated by supplying a voltage signal to a cable having wires that are galvanically separated from each other. The measuring section is further configured to test which pair of wires of the cable carries the input signal, the pair of wires being formed by a first wire and a second wire.

The apparatus may be configured or provided as a circuit. In some embodiments, the apparatus is provided as a sense and select circuit (SASC). The apparatus may be a portion of the device or may be a unit separate from the device. In some embodiments, the device may include a number of transceivers or interfaces that support a number of different communication technologies.

The cable may have at least 4 wires. For example, the cable may have between 4 and 5 wires.

The apparatus may be configured to perform a method in accordance with any of the above-described embodiments.

In some embodiments, a subsea device that includes an apparatus of a type described above is provided. The subsea device may automatically select the communication technology suitable for processing a received electrical input signal. In a subsea installation that includes a plurality of subsea devices, an upgrade to a new (and perhaps faster) communication technology may be performed by substituting one subsea device for another without losing the ability of the subsea devices to communicate with each other or with a central communication unit (e.g., a subsea control unit/module or the like). In some embodiments, the subsea device may be a subsea control module or unit.

The features of the present teachings described above and further explained below may be combined unless noted to the contrary.

### BRIEF DESCRIPTION OF THE DRAWINGS

FIG. 1 shows a schematic illustration of an example of a device configured for reception of an electrical input signal.

FIG. 2 shows a flowchart of an example of a selection algorithm for configuring a device in accordance with the present teachings.

FIG. 3 shows a schematic illustration of an example of a device that is configured for reception of an electrical input signal and for supplying an electrical output signal in accordance with the present teachings

### DETAILED DESCRIPTION

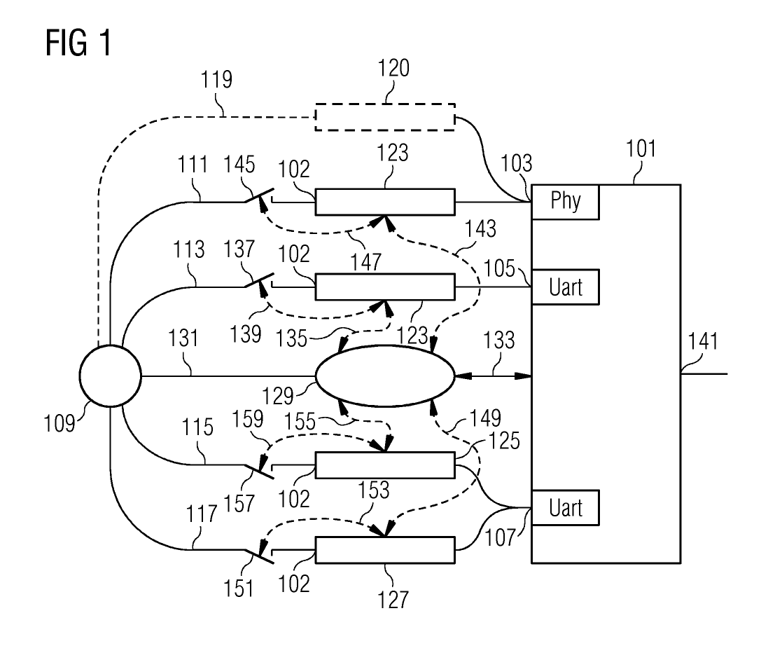

FIG. 1 shows a schematic illustration of an exemplary device that is configured for reception of an electrical input signal in accordance with the present teachings

The device 101 shown in FIG. 1 may, for example, include a pump, a compressor, or a measuring unit to support a subsea application (e.g., a gas/oil exploration procedure). The device 101 includes hardware input terminals 103 (Phy), 105 (Uart), and 107 (Uart) for receiving a communication input signal that complies with different communication standards.

The device 101 is configured for reception of an electrical input signal 109 that may comply with one of a number of different communication technologies. The input signal 109 may comply with an Ethernet technology that is represented schematically as a branch 111, with a RS-232 technology that is represented schematically as a branch 113, with a RS-485 communication technology that is represented schematically as a branch 115, or with a RS-422 communication technology that is represented schematically as a branch 117. The input signal 109 may comply with one or more other communication technologies illustrated schematically by a branch 119 that represents differential or non-differential communication technologies.

The device 101 includes a number of communication interfaces or transceivers (e.g., an Ethernet transceiver 121, a RS-232 transceiver 123, a RS-485 transceiver 125, and a RS-422 transceiver 127). The device may include more transceivers (illustrated as 120) for other technologies. The Ethernet transceiver 121, the RS-232 transceiver 123, the RS-485 transceiver 125, and the RS-422 transceiver 127 are connected to respective input terminals 103, 105 and 107 of the device 101. The device 101 is configured to receive the input signal 109 in different representations (e.g., different communication technologies).

To configure the input device 101 to receive the input signal 109 represented or transmitted using a predetermined communication technology (e.g., such as the communication technology 111, 113, 115, 117 or 119), the device 101 includes a sense and select circuit 129 that has measurement capabilities as well as configuring capabilities. In some embodiments, via a line 131, the sense and select circuit 129 performs a measurement at the input signal 109 to select from among the plurality of available communication technologies 121, 123, 125 and 127, and to send a status signal corresponding to the selected communication technology to the device 101. The status signal is indicated by a status line 133 carrying a status signal in FIG. 1.

In some embodiments, the sense and select circuit 129 may initially determine a pair at which the input signal 109 is carried, the pair including a first wire and a second wire. The sense and select circuit 129 may carry out one or more voltage measurements at the determined pair.

The sense and select circuit 129 may carry out one or more measurements to determine whether the input signal 109 complies with a non-differential input signal. In some embodiments, the sense and select circuit 129 may determine that the potential of the first wire or the second wire is the ground potential or earth potential. The sense and select circuit 129 may decide or select to utilize the RS-232 transceiver 123 to receive the input signal 109. Therefore, the sense and select circuit 129 activates, via a control line 135, the RS-232 transceiver 123. The sense and select circuit 129 further closes a switch 137 via a control signal 139 to supply the input signal 109 via the RS-232 transceiver 123 to the input terminal 105 of the device 101. Further, a status signal 133 may indicate that the RS-232 communication technology is being utilized.

The device 101 may receive the input signal 109 and process the input signal. In addition, the device may, based on the processing of the input signal 109, output one or more output signals at an output terminal 141.

If the sense and select circuit 129 determines that the input signal complies with a differential input signal, a further test may measure a voltage between the first wire and the second wire at which the input signal 109 is carried. Thus, different differential communication technologies may be distinguished from one another.

For example, the sense and select circuit 129 may determine that the maximum absolute value of the voltage between the first wire and the second wire is below 3 V. In this case, the sense and select circuit 129 may activate the Ethernet transceiver 121 via a signal line 143, and close a switch 145 via a control line 147, to supply the input signal 109 to the input terminal 103 of the device 101.

If, on the other hand, the sense and select circuit 129 determines that the voltage is below 6 V but above 3 V, the sense and select circuit 129 may activate the RS-422 transceiver 127 via a control line 149, and close a switch 151 via a control line 153, to supply the input signal 109 via the RS-422 transceiver 127 to the input terminal 107 of the device 101.

Moreover, if the sense and select circuit 129 determines that the maximum absolute value of the voltage between the first wire and the second wire is above 6 V (and, in some embodiments, below 12 V), the sense and select circuit 129 may activate the RS-485 transceiver 125 via the control line 155, and close the switch 157 via a control line 159 to supply the input signal 109 via the RS-485 transceiver 125 to the input terminal 107 of the device 101.

Table 1 illustrates different voltage levels for different physical layers or communication technologies that, at a minimum, are by a method and apparatus in accordance with the present teachings

TABLE 1

| PHYSICAL LAYER | VOLTAGE LEVEL | DIFFERENTIAL |
|---|---|---|
| Ethernet | −2.5 V . . . +2.5 V | yes |
| RS 485 | −5 V . . . +12 V | yes |
| RS 422 | −6 V . . . +6 V | yes |
| RS 232 | −3 V . . . +15 V | no |

In some embodiments, as shown in FIG. 1, the device 101 includes all physical interfaces. The sense and select circuit 129 configured the device 101, depending on the characteristics of the input signal 109, to activate the appropriate transceiver 121, 123, 125 and 127 that corresponds to the communication technology with which the input signal 109 complies. In some embodiments, the device 101 may retain the chosen communication interface until a next power-on sequence. In some embodiments, the selection of the appropriate interface may be performed only during a start-up or boot-up of the device 101.

The method and the apparatus in accordance with the present teachings provide a solution that extends old and new communication signaling technologies to existing and new devices, such as device 101. In some embodiments, the sense and select circuit (SASC) 129 detects the voltage level on the physical layer for incoming communication packages after powering on the device 101. After a decision has been made regarding the type of communication protocol on the incoming signal 109, the SASC activates the transceiver corresponding to the input signal and closes one of the switches 145, 137, 157, 151 to supply the input signal 109 to the selected transceiver. After sensing and selecting the correct input, activating the correct transceiver, and connecting that transceiver to the input pins, the SASC may tell the device 101 what type of communication is to be used for the status line 133.

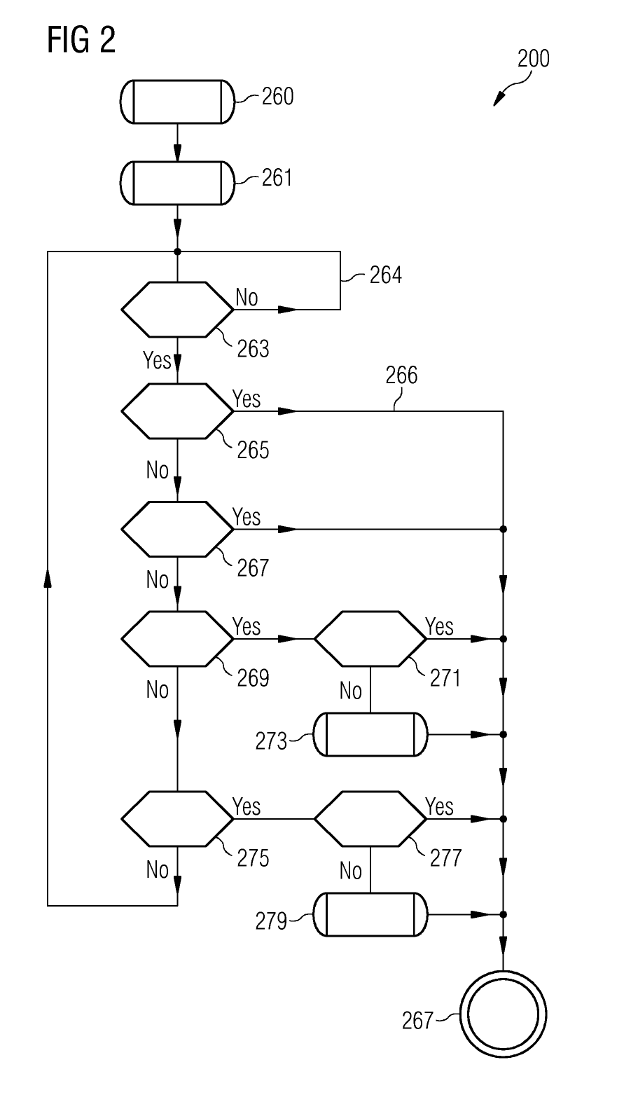

FIG. 2 shows a flowchart 200 of an exemplary method for configuring a device in accordance with the present teachings. At method act 260, the device is powered on. At act 261, an initiation phase is entered. At decision block 263, a determination is made as to whether there is any input voltage at any wire of the cable that is used for communication. If no voltage is detected, the method proceeds to a branch 264 leading back to act 263. If a voltage is detected, a determination is made at decision block 265 as to whether the voltage is compliant with the RS 232 technology. If the voltage is compliant with the RS 232 technology, the method proceeds to a branch 266 that eventually leads to activating the technology RS 232 and normal operation 267.

If the RS 232 technology is not detected, a determination is made at decision block 267, by measuring the voltage between the first wire and the second wire, as to whether Ethernet technology is used. If Ethernet technology is being used, the Ethernet technology is activated and normal operation 267 is reached. If Ethernet technology is not being used, a determination is made at decision block 269 as to whether RS 422 technology is used. If RS 422 technology is being used, a determination is made at decision block 271 as to whether the RS 422 technology uses two wires. If the RS 422 technology uses two wires, the two-wire RS 422 technology is activated and normal operation 267 is reached. If the RS 422 technology does not use two-wire communication, the method proceeds to act 273 wherein four-wire RS 422 technology is activated and normal operation 267 is reached.

If the test at decision block 269 indicates that RS 422 technology is not being used, a determination is made at decision block 275 as to whether the technology or the input signal (e.g., input signal 109 illustrated in FIG. 1) complies with RS 485 technology. If the technology or input signal complies with RS 485 technology, a determination is made at decision block 277 as to whether the RS 485 technology uses two wires. If the RS 485 technology uses two wires, the two-wire RS 485 technology is activated and normal operation 267 is reached. If the RS 485 technology does not use two wires, the four-wire RS 485 technology is activated in method act 279 and normal operation 267 is reached.

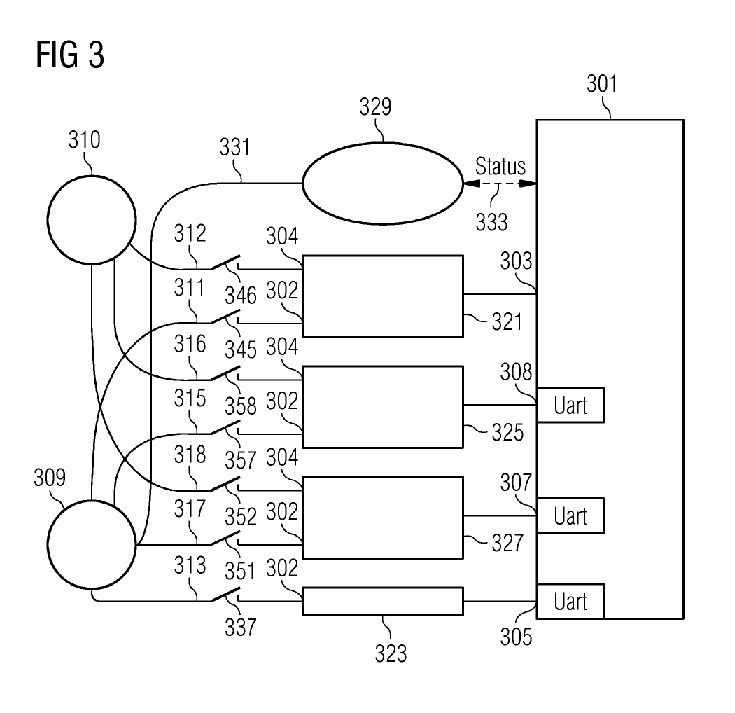

FIG. 3 shows a schematic illustration of an exemplary device 301 that is being configured in accordance with the present teachings for receiving input and supplying output.

In FIG. 3, a component, unit, or element that is similar in structure and/or function to a component, unit, or element illustrated in FIG. 1 is labeled with a reference sign that differs only in its first digit.

In FIG. 1, for simplicity, the transceivers 121, 123, 125, 127 and 120 are shown only as having input terminals 102 for receiving the input signal 109. When the respective transceiver is activated, one of the respective switches 145, 137, 157 or 151 is closed to supply the input terminal 109 to the selected and activated transceiver. The transceivers 321, 325, 327 and 323 shown in FIG. 3 have input terminals 302 to receive the input signal 309 when one of the respective switches 345, 357, 352, or 337 is closed after having selected the respective communication technology based on the measurements on the input signal 309.

As shown in FIG. 3, all inputs are wired together and all outputs are wired together. Thus, one input/output is used for different signal levels but not at the same time. Selection as described in reference to FIG. 1 may be carried out according to the exemplary scheme illustrated in FIG. 2 and performed during start-up of the device 301. In some embodiments, selection may be carried out after power is supplied to the device or processing unit 301.

In the initiation phase shown by act 261 in FIG. 2, the sense and select circuit 129, 329 is activated after powering on the device 301. At this moment, none of the input switches 345, 357, 351 or 337 is closed, and the sense and select circuit 329 is listening to the input signal 309 and sensing or measuring the voltage level of, in some embodiments, the first wire and the second wire included in the communication cable. The first wire and the second wire carry the input signal 309.

A selection phase is entered after the initiation phase. During the selection phase, the system selects between one and only one of the communication technologies and activates the respective transceiver. Depending on the results of the measurements performed at the input signal 309, one of the input switches 337, 351, 357 or 345 is closed, and the respective transceiver 323, 327, 325 or 321 is activated to receive the input signal 309.

For the sake of clarity, the different states wherein one of the input switches is closed are not shown in FIG. 3.

If a determination is made that Ethernet technology is used, the output switch 346 is closed, thereby connecting the output terminal 304 of the Ethernet transceiver 321 to the output wires 310.

The RS 422 technology, as well as the RS 485 technology, may be operated in two different variants (e.g., a two-wire variant and a four-wire variant). When the two-wire variant is used, only the respective input switches (e.g., the input switch 351 or the input switch 357) are closed without closing the output switches 352 and 358.

If these technologies are operated in the four-wire variant, the output switches 352 or 358 are also closed to connect the output terminals 304 of the respective transceiver to the output wires 310 that are used to carry an output signal that is output from the respective transceiver.

As used herein, the term “comprising” does not exclude additional elements or acts, and the indefinite articles “a” and “an” do not exclude a plurality. In addition, elements described in association with different embodiments may be combined to provide further embodiments.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. A method for configuring a device to receive an electrical input signal, the method comprising:
generating the electrical input signal in compliance with a predetermined communication technology;
performing a measurement of the electrical input signal;
selecting, based on a result of the measurement, the predetermined communication technology for receiving the electrical input signal at the device from a plurality of available communication technologies supported by the device;
activating the device to receive the electrical input signal according to the predetermined communication technology;
wherein the generating of the electrical input signal comprises supplying a voltage signal to a cable that comprises galvanically separated wires; and
wherein the performing of the measurement of the electrical input signal comprises determining a pair of wires of the cable that carries the electrical input signal, the pair being formed by a first wire and a second wire.

2. The method of claim 1, wherein the cable comprises at least 4 galvanically separated wires.

3. The method of claim 1, wherein the performing of the measurement of the electrical input signal further comprises comparing an electrical potential of the first wire, the second wire, or the first wire and the second wire to a ground potential; and
wherein, if the electrical potential of the first wire or the second wire is the ground potential, the RS 232 communication technology is selected.

4. The method of claim 1, wherein the performing of the measurement of the electrical input signal further comprises measuring a voltage between the first wire and the second wire.

5. The method of claim 4, wherein if a maximum absolute value of the voltage is below 3 V, the Ethernet communication technology is selected.

6. The method of claim 4, wherein if a maximum absolute value of the voltage is above 3 V and below 6 V, the RS 422 communication technology is selected.

7. The method of claim 4, wherein if a maximum absolute value of the voltage is above 6 V, the RS 485 communication technology is selected.

8. The method of claim 1, wherein each of the plurality of available communication technologies and the predetermined communication technology comprises a data package-based protocol.

9. The method of claim 1, wherein the generating of the electrical input signal further comprises generating a signal pattern that comprises a time sequence of logical true and logical false values;
wherein the measurement is performed based on the signal pattern;
wherein a clock speed of the predetermined communication technology is considered when the measurement is performed or when a result is derived from the performed measurement; and
wherein the measurement is performed across at least 10 clock cycles.

10. The method of claim 1, further comprising:
activating a transceiver or an interface of the device, wherein the transceiver or the interface is configured for the predetermined communication technology; and
actuating a switch to supply the electrical input signal to the transceiver or the interface.

11. The method of claim 10, wherein the actuating of the switch comprises connecting the first wire and the second wire to input terminals of the activated transceiver.

12. The method of claim 10, wherein the actuating of the switch comprises connecting a third wire of the cable and a fourth wire of the cable to output terminals of the activated transceiver.

13. The method of one of claim 1, further comprising:
notifying the device of the predetermined communication technology to be used.

14. An apparatus for configuring a device to receive an electrical input signal, the apparatus comprising:
a measuring section configured to perform a measurement of an electrical input signal in compliance with a predetermined communication technology;
a selection section configured to select, based on a result of the measurement, the predetermined communication technology for receiving the electrical input signal at the device from a plurality of available communication technologies supported by the device; and
a control section configured to activate the device to receive the electrical input signal according to the predetermined communication technology;
wherein the electrical input signal is generated by supplying a voltage signal to a cable that comprises galvanically separated wires; and
wherein the measuring section is further configured to determine a pair of wires of the cable that carries the electrical input signal, the pair being formed by a first wire and a second wire.

15. The apparatus of claim 14, wherein the cable comprises at least 4 wires.

16. The method of claim 1, wherein the cable comprises between 4 and 5 galvanically separated wires.

17. The method of claim 1, wherein the performing of the measurement of the electrical input signal further comprises measuring a voltage between the first wire and the second wire for plural communication clock cycles.

18. The method of claim 1, wherein each of the plurality of available communication technologies and the predetermined communication technology comprises a data package-based protocol selected from the group consisting of Ethernet, RS 485, RS 422, RS 232, and combinations thereof.

19. The method of claim 1, wherein the generating of the electrical input signal further comprises generating a signal pattern that comprises a time sequence of logical true and logical false values;
wherein the measurement is performed based on the signal pattern;
wherein a clock speed of the predetermined communication technology is considered when the measurement is performed or when a result is derived from the performed measurement; and
wherein the measurement is performed across between 100 and 1000 clock cycles.

20. The method of claim 10, wherein the actuating of the switch comprises connecting a third wire of the cable and a fourth wire of the cable to output terminals of the activated transceiver if it is determined that the RS 422 technology or the RS 485 technology uses four wires.
